(19) United States
(12) Patent Application Publication
(10) Pub. No.: US 2010/0328219 A1
(43) Pub. Date: Dec. 30, 2010

(54) Method for Integrating an Imager and Flash into a Keypad on a Portable Device

(75) Inventors: Michael J. Lombardi, Lake Zurich, IL (US); Christopher A. Arnholt, Highland Park, IL (US); Frank H. Stone, Waukegan, IL (US); Michael Spence, Libertyville, IL (US); Simon F. Vollmer, Hawthorn Woods, IL (US)

Correspondence Address: Tolpin & Partners, PC, 11 S. LaSalle Street, Suite 2900, Chicago, IL, 60603, US

(73) Assignee: Motorola, Inc., Schaumburg, IL (US)

(21) Appl. No.: 12/494,982

(22) Filed: Jun. 30, 2009

(51) Int. Cl. G06F 3/02; H03M 11/00

(52) U.S. Cl. 345/169; 341/23

(57) ABSTRACT

An improved mobile electronic device 100 with a unique thin and cost-effective form and design can have a large display 170 and a large full qwerty keypad 138. The keypad can have a camera 156 and flash 154 with a light barrier 158. A clear moldprint keypad can be used with graphics 148 on the backside of the keypad. The keypad can be positioned over a series of switches 162 or domes. The keypad 138 can further be recessed below the rim 136 of the housing 134 of the base so that the keypad will not contact a table or desk and be inadvertently activated if the keypad is placed face down. The moldprint keypad can be used to minimize wear of the graphics 148 and can have a specific textured pattern over the flash which can act as a lens to maximize light.

### BACKGROUND OF THE INVENTION

1. Field of the Disclosure

The disclosure relates in general to mobile devices, keypads, and more particularly, to mobile electronic devices with an electronic display and a keypad. In certain embodiments, the mobile electronic device comprises a mobile telephone, but the disclosure is not limited to mobile telephones.

2. Background Art

There is a significant market for mobile electronic devices with large displays coupled with large, full qwerty keypads. To fulfill this need, a unique, thin, and cost-effective mobile electronic device with a keypad on the back of a clamshell device and a single display on the front of the device has been developed.

Typical placement of a camera or other imager on a mobile device occurs on the back surface of the mobile electronic device, opposite the viewable area of the display. For some mobile electronic devices, this surface is used for a keypad.

Furthermore, there is a need to better protect the keypad of mobile electronic devices.

It is, therefore, desirable to provide an improved keypad assembly and mobile electronic device, which overcome most, if not all of the preceding disadvantages.

### SUMMARY OF THE INVENTION

An improved mobile electronic device with a unique thin and cost-effective form and design is provided that is user-friendly, reliable, fun and effective. The attractive mobile electronic device can have a large capacitive display on the outward surface of a flip or slide, a large full qwerty keypad on the outward surface of a base and can have a capacitive touchpad on the inward surface of the flip or slide that facilitates navigation on the display. The multi-functional mobile electronic device is easy to use, comfortable and economical.

The mobile electronic device can be a radiotelephone, a cellular (cell) phone, a mobile phone, smart phone, flip phone, slider phone, portable networking device, qwerty flip device, wireless device, portable gaming device, mobile communications device, personal digital assistant (PDA), wireless e-mail device, a two way pager, internet communication device, hand held electronic device, or combinations of the preceding. Desirably, the mobile electronic device is of a compact size for readily fitting in a shirt pocket, pants pocket, suit pocket, and/or purse.

In the novel keypad assembly within the mobile electronic device, the keypad can be recessed below the rim or tallest (highest) portion of the housing of the base to ensure that the keypad surface is protected and will not contact a tabletop or other surface so that the keypad cannot be inadvertently activated or touched, to make an unwanted phone call or transmit a false signal, if the keypad is placed face down on a table or other surface. The improved mobile electronic device can also have a moldprint keypad for second-surface decoration of the keypad to minimize retards and/or eliminates wearing, fading, blurring, discoloration, deterioration, scratching, etc. of the graphics on the keypad.

The inventive keypad assembly can have a camera, camera lens, zoom lens, webcam or other image capture device and/or a flash, light emitting diode (LED), light-emitting bulb, or other illumination source within the boundaries or area of the keypad. In the preferred embodiment, a clear moldprint keypad is used with decoration and/or other graphics techniques on the backside of the keypad. This keypad can be positioned over a series of switches or domes which a user can depress and over an imaging device and/or illumination device. The keypad can remain intact with clear windows over the flash and imager or have cutouts in which lenses of other materials such as glass or transparent plastic can reside. Furthermore, if left intact over the illumination source, the moldprint keypad can have a specific textured pattern tooled into the moldprint surface on the front or rear side of the keypad which can act as a lens to maximize light output from the illumination source.

In the mobile electronic device, the camera or other imager can be positioned within keypad perimeter or keypad area to allow for video conferencing or self portrait image capture in the open position of the mobile electronic device and still image capture in the closed position of the mobile electronic device. The described arrangement also allows the keypad to act as protective lens for the imager, if the keypad is clear or the keypad can have a hole in it for the imager to port through.

A flash present within keypad perimeter or keyboard area can be provided for cost savings and improved performance. Patterns can be molded into the keypad over the LED flash or other flash to focus the light and act as a lens for the flash.

A light barrier comprising a gasket, housing, ribs, etc. can be positioned between the flash LED, imager, and keypad backlight area so as to minimize or eliminate light from the flash leaking into the graphics of the keypad.

The keypad can be transparent, clear and light transmissive. The graphics on the keypad can comprise: text, numbers, characters, alpha numeric images, color graphics, black graphics, moving graphics, animation, video clips, logos, photographs, decorations, designs, symbols, and other images. Graphics can be printed or otherwise placed on the backside of the qwerty keypad so that if abrasion occurs on front surface, the graphics do not wear away.

The recessed keypad preferably sits and is positioned below the surrounding housing so that when the back surface of the mobile electronics device contacts a flat surface such as a tabletop, the rim or top of the housing sits on the flat surface and not the keypad. Furthermore, by using a recessed moldprint keypad, abrasion damage to the keypad surface can be reduced.

The disclosed imager placement can provide for improved mobile electronic devices with keypads on their back surface without sacrificing ideal imager location.

The mobile electronic device can comprise a base and a movable portion, such as a flip, that is operatively connected to the base, such as by a hinge. The movable portion is movable from an open position to a closed position and vice versa. The mobile electronic device can further comprise: a keypad assembly and a touchscreen comprising a display on the outward surface of the movable portion. The keypad assembly can comprise a housing with a rim that provides a top of the housing and can comprise a keypad on the outward surface of the base.

The keypad of the mobile electronic device can include an imager, such as a camera for video conferencing in the open position of the flip and for still image photography in the closed position of the flip. The keypad can further include a flash, such as a light-emitting diode (LED) or other illumination source, which can be positioned in proximity to the imager. A pattern can be molded over the flash for focusing light emitted from the flash and providing a lens for the flash. The keypad assembly can also comprise a light barrier for substantially preventing the flash from illuminating graphics on the keypad and for substantially minimizing hot spots in images captured by said imager. The light barrier can comprises a light-blocking gasket for substantially preventing the backlighting from leaking beyond the keypad perimeter, being visible through the imager and being visible about the flash.

The keypad can be a capacitive keypad, such as with a capacitive touch surface with a touch sensor or press key. In the preferred embodiment, the keypad comprises a recessed keypad positioned below the maximum elevation or height of the rim providing a top of said housing so that when the keypad assembly is placed on a surface of a table, desk or shelf, the rim engages the surface, but the recessed keypad is prevented from touching or otherwise engaging the surface.

This invention as described in the specification and patent claims achieves intended results and excellent performance.

A more detailed explanation of the invention is provided in the following detailed descriptions and appended claims taken in conjunction with the accompanying drawings.

### BRIEF DESCRIPTION OF THE DRAWINGS

FIG. 1 is a front view of a mobile electronic device in accordance with principle of the present invention of the present disclosure shown in a closed position in a tablet mode in which the flip and base are positioned at a zero (0) degree angle relative to each other.

FIG. 2 is a side view of the mobile electronic device shown in the closed position in the tablet mode.

FIG. 3 is a perspective view of the mobile electronic device shown in a partially open position in a media viewing mode.

FIG. 4 is a side view of the mobile electronic device shown in the partially open position in the media viewing mode.

FIG. 5 is a perspective view of the mobile electronic device shown in a fully open position in a text entry mode.

FIG. 6 is a side view of the mobile electronic device shown in the fully open position in the text entry mode.

FIG. 7 is a front view of the mobile electronic device shown in the open position.

FIG. 8 is a back view of the mobile electronic device shown in the open position.

FIG. 9 is an enlarged view of the keypad assembly on the back surface of mobile electronic device.

FIG. 10 is an enlarged cross-sectional view of part of the keypad and housing of the base.

### DETAILED DESCRIPTION OF THE INVENTION

The following is a detailed description and explanation of the preferred embodiments of the invention and best modes for practicing the invention.

Referring to the drawings, a mobile electronic device 100 can comprise a flip 102 which can be pivotally connected by a hinge 104 to a base 106. The flip can be pivotable from a closed position, to partially open positions and to a fully open position and vise versa. The mobile electronic device can be movable to different orientations for providing different functionality in the partially open positions.

The mobile electronic device can be: a flip phone, slider phone, portable networking device, internet communications device, clamshell device, radio telephone, cellular phone, mobile phone, smart phone, portable gaming device, personal digital assistant, wireless e-mail device, two-way pager, handheld electronic device, or combinations of the preceding. The mobile electronic device preferably is of a compact size for readily fitting in a shirt pocket, pants pocket, suit pocket, and/or purse.

The base and the flip each can have an outward (outer) surface 108 or 110, an inward (inner) surface 112 or 114, edges comprising longitudinal sides 115, 116, 117 or 118 in a portrait mode, and lateral ends 119, 120, 121 or 122 in a portrait mode.

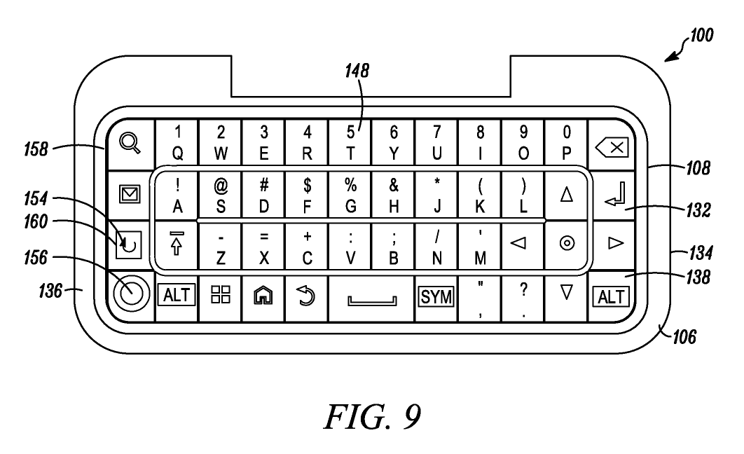

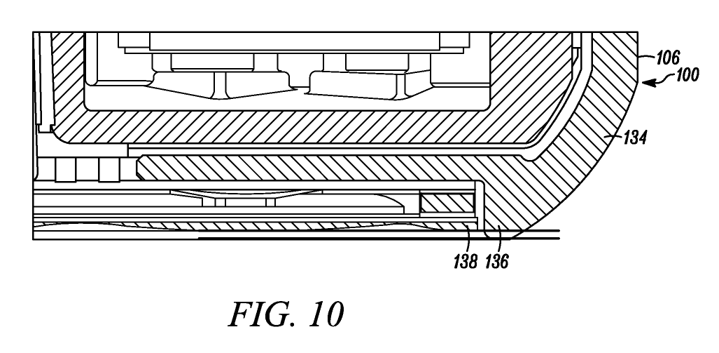

The base can have a keypad assembly 132 (FIG. 9) which can comprise housing (keypad housing) 134 with a rim 136 that can provide a periphery and perimeter that can surround or partially surround a keypad 138. The keypad assembly can have backlighting 140 below the keypad. The keypad can be positioned on the outward surface of the base and can face downwardly when the flip is in the partially open position, such as in a media viewing mode. The keypad can be partially transparent, optically clear and light transmissive and can have key caps. The keypad can comprise: a qwerty keypad, capacitive keypad, keyboard, alpha numeric keys, a base touchscreen, or combinations of the preceding. The keypad can have a capacitive touch surface with a touch sensor. The keypad can occupy most, preferably 70% to 99% of the outward surface of the base.

The keypad can also comprise a moldprint keypad with graphics 148 (FIG. 15) on an underside of the keypad or on a layer below the keypad. Such graphics for the keypad can include one or more of the following: text, numbers, characters, alpha numeric images, color graphics, black graphics, moving graphics, animation, video clips, logos, photographs, decorations, designs, symbols, and other images.

The keypad can comprise a recessed keypad positioned below the maximum elevation or height of the rim which provides the top of said housing so that when the keypad assembly is placed on a support surface, such as a table, desk, or shelf, the rim engages the surface, but the recessed keypad is spaced above the support surface and prevented from touching or otherwise engaging the support surface.

The keypad can include a flash 154, such as an light-emitting diode (LED), light-emitting bulb, or other illumination source, in proximity to an imager 156 (image capture device), such as a camera, webcam, camera lens, zoom lens, webcam, or other image capture device. The image capture device and flash can occupy one or more of the key caps. The keypad assembly can include a light barrier 158, such a compressible light-blocking gasket or ribs, for substantially preventing the flash from illuminating graphics on the keypad and for substantially minimizing hot spots or flare in images captured by the imager. Desirably, the light-blocking gasket can also prevent the backlighting from being visible through the imager and about the flash or flash hole. A pattern 160 can be molded into the keypad over the flash for focusing light emitted from the flash and providing a lens for the flash.

A display structure assembly 164 can provide a display module 166 with display housing 168 and a touchscreen display 170 on the outward surface of the flip. The display can be positioned opposite the keypad when the flip is in a closed position in a tablet mode. The display can face upwardly with and in proximity to the keypad when the flip in a fully open position in an e-mail/text mode. The display can be positioned at an angle of inclination when the flip is in a partially open position in a media viewing mode. The display can occupy most, preferably 70% to 99% of the outward surface of the base.

The display can comprise a touchscreen comprising a touch sensitive lens 172 with an input lens surface 174. Touch sensors 176 can be integrated to either the input surface or the opposite surface of the lens. The touch sensor generates a signal in response to an input from a user when the user touches the lens. The touchscreen display can be can be transparent, clear and light transmissive and can comprise a capacitive touchscreen, an organic light emitting display (OLED) or a liquid crystal display (LCD).

A touchpad assembly 186 can provide a touchpad sensor and a touchpad cover. The touchpad assembly can also have a housing, with or without a rim, for holding the touchpad, such as with adhesive. A touchpad gasket can be positioned between and sealing the touchpad housing to a peripheral portion of the touchpad.

The touchpad can be positioned on the inward surface of the flip at a location which is transversely opposite of the display. The touchpad can provide navigation control within the user interface (UI) on the display, such as, but not limited to: highlighting a web link on the display, scrolling through text on the display, clicking to enter a command on the display, and/or implementing a mouse cursor on the touchscreen. The touchpad can also comprise one or more of the following: zoom control, a magnifier, scroll bar, scroll control, a slide bar in a browser window, enter key, command key, shift key, visual selector, cursor, and/or pointer. The touchpad can occupy a substantial portion, such as from 25% to 75%, of the inward surface of the flip. In the illustrative embodiment, the touchpad is smaller and occupies a smaller area than either the touchscreen display or the keypad.

Advantageously, the touchpad is positioned to be touched by the user without blocking viewing of the display when the flip is in the partially open and fully open positions. The touchpad can be hidden and inaccessible when the flip is in the closed position.

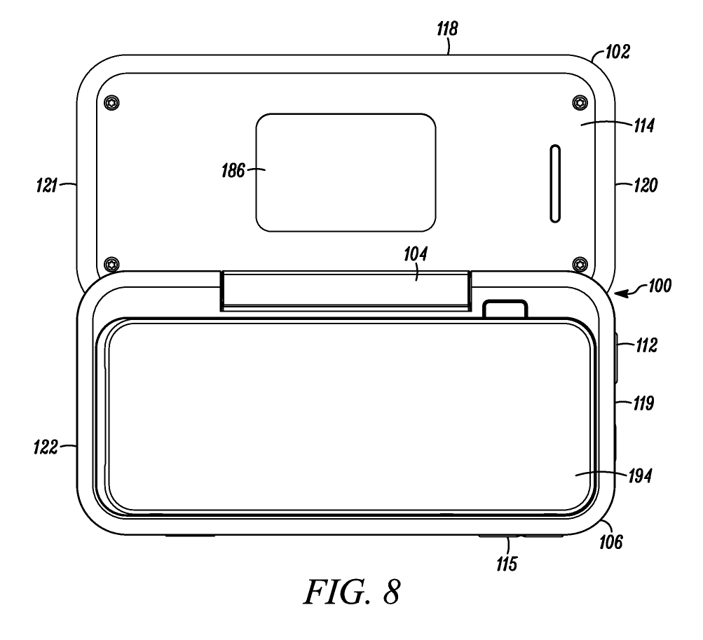

A removable battery door 194 (FIG. 8) can be positioned along the inward surface or outward surface of the base at a location transversely opposite of the keypad. The removable battery door can be hidden and inaccessible when the flip is in the closed position.

A speaker port can be hidden underneath the removable battery door. The speaker port can provide an acoustical passageway for emitting sound from the speaker.

The hinge can comprise a friction hinge which can have a radial range of motion of 180 degrees or more and can have detents at both ends of travel. This can be achieved through the use of an asymmetrical cam in conjunction with a single tab on a follower. The friction hinge also provides a dependable and inexpensive way to produce a tilt in the display of a qwerty flip device or in a qwerty mode.

In particular, the friction hinge can comprise a pivotable asymmetrical cam and a follower mounted on a pivotable or rotatable shaft that provides a pivot pin and an axis of rotation. A coil spring, such as a compression spring, can be positioned about the shaft to urge and bias the face of the cam against the single tab of the follower.

The asymmetric cam can have a cam face which provides an asymmetrical cam surface upon which the follower rides. The asymmetrical cam surface can have two or more detents including, but not limited to, a first detent at a zero (0) degree position for closing the electronic device and a second detent at a position at or beyond 180 degrees so that the electronic device can be partially opened and subsequently pivoted to a fully opened position with the flip opened at an angle at or beyond 180 degrees relative to the base. The detents of the asymmetrical cam can be separated by 210 degrees to allow for 190 degrees of travel and 10 degrees of preload at both ends of travel. In some circumstances, it may be desirable that the cam has more than two detents. The asymmetrical cam can have diametrically opposite curved surfaces diametrically opposite generally flat planar surfaces.

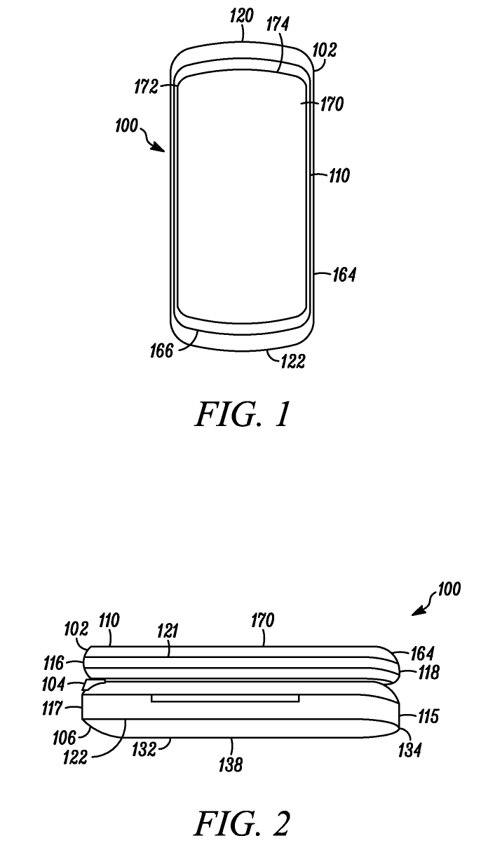

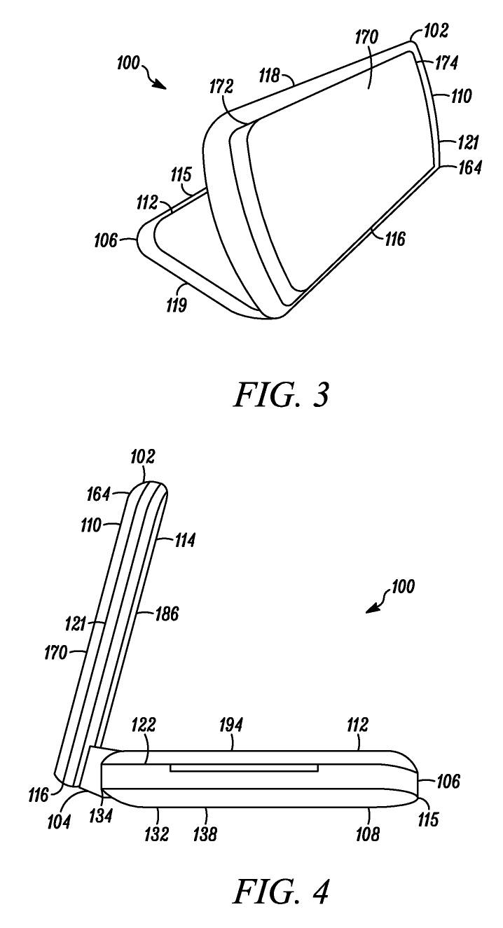

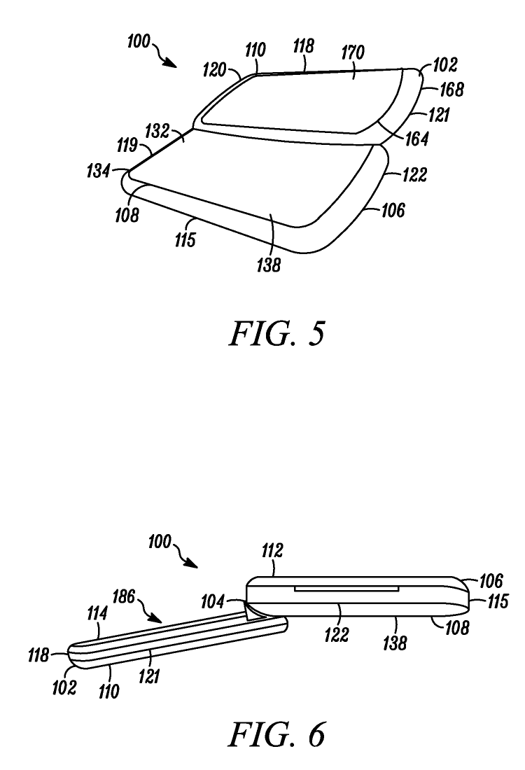

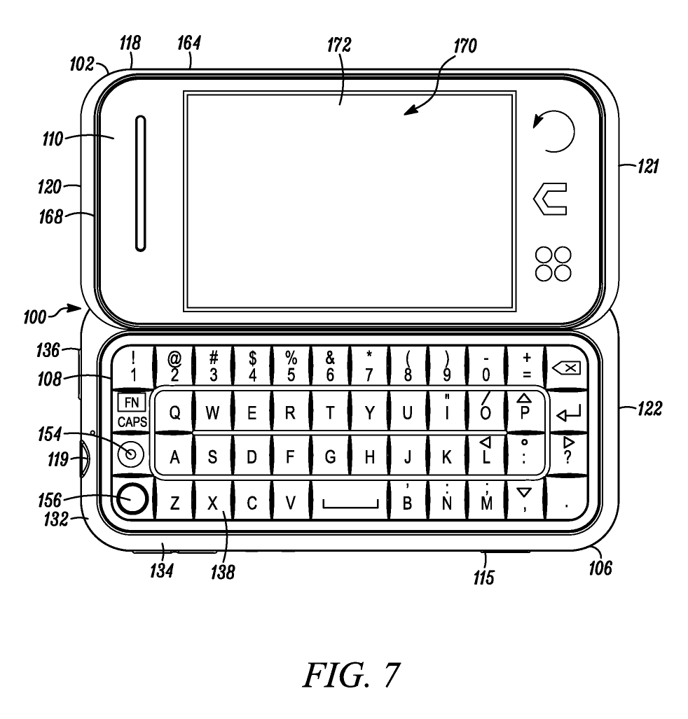

Advantageously, the friction hinge provides specific positions of the electronic device including: (1) a closed position in a tablet mode as shown in FIGS. 1 and 2 in which the flip and base are positioned at a zero (0) degree angle relative to each other at a closed torque, (2) a fully open position in a qwerty/text-entry mode as shown in FIGS. 5 and 6 in which the flip and base are positioned at a open angle at or substantially greater than about 180 degrees at a fully open torque, and (3) a partially open position in a media viewing mode as shown in FIGS. 3 and 4 in which the flip and base are positioned at an open angle substantially greater than the closed position but substantially less than fully open position at a torque less than the closed torque and the fully open torque.

In the preferred embodiment, the partially open position in the media viewing mode ranges from 70 degrees to 100 degrees and the fully open position is 180 degrees to 190 degrees in the qwerty mode.

In operation and use, in the tablet mode of FIGS. 1 and 2, the flip is held closed using the first detent in the cam. In the closed position, the interior inwardly facing inward surfaces of the flip and base abut and face each other so as to be hidden from view in the interior of the electronic device and are not accessible to the user. In the closed position in the tablet mode, the exterior outer surfaces of the flip and base are visible and accessible to the user.

In the media viewing mode as shown in FIGS. 3 and 4, the user sets of the desired angle of the flip and the flip is then held open with a holding torque produced by the friction between the asymmetrical cam and the follower. In the partially open, media viewing mode, the user sets the desired angle of the flip to access the inward surfaces of the flip and base.

In the fully open position as shown in FIGS. 5 and 6, the flip is held open about 190 degrees using the second detent in the asymmetrical cam. In the fully open position, the user can readily and fully access the touchpad, keypad, battery door and touchscreen display.

The mobile electronic device can have a touchpad or touch-detecting surface on the rear of a flip or slide device for use as input mechanism. This provides a natural location of pointer fingers when holding the base of the mobile electronic device, so that the user does not need to block the display comprising a touchscreen to navigate and select items on the touchscreen, nor does the user need navigation keys on the keypad in the base.

This mobile electronic device can utilize the rear surface of the flip portion of the mobile electronic device for user interface (UI) navigation. When the mobile electronic device is fully opened, a capacitive or resistive touchpad is positioned on the inward surface of the flip or slide directly behind the display in the outward surface of the flip or slider portion of the mobile electronic device. When the touchpad is touched by the user, the motion of the finger translates to motion within the UI on the forward facing display. This can include highlighting different web links or scrolling through text. It can also include implementing a mouse cursor on the UI which follows the motion of a user's finger on the back of the mobile electronic device.

The imager and flash devices embedded within the keypad perimeter is unique and offers many advantages. The light barrier prevents backlighting from escaping beyond the perimeter of the keypad and prevents flare or hotspots from appearing in captured images. The position in the base allows for video conference functionality when the flip is opened and still image capture functionality when the flip is opened (self-portrait) or closed.

Among the many advantages of the mobile electronic device are:
1. Superior capability.
2. Superb performance.
3. Enhanced imaging.
4. Consistent lighting.
5. Reliable.
6. Comfortable.
7. Light weight.
8. Portable.
9. User friendly.
10. Easy to use.
11. Durable
12. Economical.
13. Attractive.
14. Efficient.
15. Effective.

Although embodiments of the invention have been shown and described, it is to be understood that various modifications, substitutions, and rearrangements of parts, components, and/or process (method) steps, as well as other uses of the mobile electronic device can be made by those skilled in the art without departing from the novel spirit and scope of this invention.

What is claimed is:

1. A keypad assembly comprising:
a keypad, said keypad having of a plurality of key caps;
a light-blocking barrier;
an image capture device; and
a backlight for the keypad.

2. A keypad assembly in accordance with claim 1 wherein;
said keypad comprises an optically clear base material with graphics printed on the back surface of said keypad or on the front surface of said keypad; and
said graphics are selected from the group consisting of text, numbers, characters, alpha numeric images, color graphics, black graphics, moving graphics, animation, video clips, logos, photographs, decorations, designs, symbols, images, and combinations thereof.

3. A keypad assembly in accordance with claim 1 wherein said keypad forms a continuous cover over said image capture device to act as a lens.

4. A keypad assembly in accordance with claim 1 wherein said keypad comprises a hole over said image capture device to allow for the use of a more optically clear material such as glass as a lens for the image capture device.

5. A keypad assembly in accordance with claim 1 wherein said light-blocking barrier comprises a compressible, substantially light-blocking gasket which allows actuation of said keypad and blockage of light.

6. A keypad assembly in accordance with claim 1 wherein said keypad comprises a flash for use with said image-capture device and said flash is selected from the group consisting of a light-emitting diode, a light-emitting bulb, and an illumination source.

7. A keypad assembly in accordance with claim 6 wherein said image capture device and said flash reside within the perimeter of said keypad.

8. A keypad assembly in accordance with claim 6 wherein said image capture device and said flash occupy one or more of said key caps.

9. A keypad assembly in accordance with claim 6 wherein said keypad includes a pattern molded over said flash for focusing light emitted from the flash and providing a lens for the flash.

10. A keypad assembly in accordance with claim 6 wherein:
said light-blocking barrier substantially prevents said flash from illuminating graphics on said keypad;
said light-blocking barrier substantially prevents said backlight from leaking beyond said keypad perimeter; and
said light-blocking barrier substantially prevents said backlight and said flash from creating flare or hot spots in images captured by said image capture device.

11. A mobile electronic device comprising:
a base;
a flip pivotably connected to said base, said flip being pivotable from a closed position, to a partially open position and to a fully open position and vise versa;
said base and said flip each having an outward surface and an inward surface;
a base assembly comprising a housing with a rim providing the outward surface of said base, a keypad on the outward surface of said base, backlighting below said keypad, said keypad being selected from the group consisting of a qwerty keypad, capacitive keypad, keyboard, alpha numeric keys, and a base touch screen, and said keypad facing downwardly when said flip is in said partially open position;
a display on the outward surface of said flip, said display being selected from the group consisting of a touchscreen display, liquid crystal display (LCD), organic light emitting diode (OLED) display, and other display technology, said display being positioned opposite said keypad when said flip is in a closed position, said display facing upwardly with and in proximity to said keypad when said flip in a fully open position, and said display being positioned at an angle of inclination when said flip is in a partially open position; and
said keypad comprises an image-capture device providing an imager.

12. A mobile electronic device in accordance with claim 11 wherein said image-capture device comprises a camera for video conferencing in the open position of the flip and for still image photography in the closed position of the flip.

13. A mobile electronic device in accordance with claim 11 wherein said keypad comprises a flash selected from the group consisting of a light-emitting diode, a light-emitting bulb, and an illumination source.

14. A mobile electronic device in accordance with claim 13 including a pattern molded into said keypad over said flash for focusing light emitted from the flash and providing a lens for the flash.

15. A mobile electronic device in accordance with claim 13 wherein:
said flash is positioned in proximity to said imager;
said keypad assembly comprises a light barrier for substantially preventing the flash from illuminating graphics on said keypad and for substantially minimizing hot spots or flare in images captured by said imager;
said light barrier comprises a light-blocking gasket for substantially preventing the backlighting from being visible through the imager and about the flash.

16. A mobile electronic device in accordance with claim 11 wherein:
said keypad comprises a recessed keypad positioned below the maximum elevation or height of the rim of the housing so that when the device is placed on a surface of a table, desk, or shelf, the rim engages the surface, but the recessed keypad is substantially prevented from touching or otherwise engaging the surface;
said mobile electronic device is selected from the group consisting of a flip phone, portable networking device, internet communications device, clamshell device, radio telephone, cellular phone, mobile phone, smart phone, portable gaming device, personal digital assistant, wireless e-mail device, two-way pager, handheld electronic device, and combinations thereof; and
said mobile electronic device is of a compact size for readily fitting in a shirt pocket, pants pocket, suit pocket, and/or purse.

17. A mobile electronic device in accordance with claim 11 wherein:
said keypad comprises a moldprint keypad with graphics on an underside of said keypad or on a layer below said keypad; and
said graphics selected from the group consisting of text, numbers, characters, alpha numeric images, color graphics, black graphics, moving graphics, animation, video clips, logos, photographs, decorations, designs, symbols, images, and combinations thereof.

18. A mobile electronic device comprising:
a base;
a flip pivotally connected to said base, said flip being pivotable from a closed position, to a partially open position and to a fully open position and vise versa;
said base and said flip each having an outward surface and an inward surface;
a base assembly comprising a housing with a rim providing the outward surface of said base, a keypad on the outward surface of said base, and backlighting below said keypad, said keypad being selected from the group consisting of a qwerty keypad, capacitive keypad, keyboard, alpha numeric keys, and a base touch screen, and said keypad facing downwardly when said flip is in said partially open position;
a display on the outward surface of said flip, said display being selected from the group consisting of a touchscreen display, liquid crystal display (LCD), organic light emitting diode (OLED) display, and other display, said display being positioned opposite said keypad when said flip is in a closed position, said display facing upwardly with and in proximity to said keypad when said flip in a fully open position, and said display being positioned at an angle of inclination when said flip is in a partially open position;
said keypad comprises a recessed keypad positioned below the maximum elevation or height of the rim of the housing so that when the keypad assembly is placed on a surface of a table, desk, or shelf, the rim engages the surface, but the recessed keypad is substantially prevented from touching or otherwise engaging the surface;
said mobile electronic device is selected from the group of consisting of a flip phone, portable networking device, internet communications device, clamshell device, radio telephone, cellular phone, mobile phone, smart phone, portable gaming device, personal digital assistant, wireless e-mail device, two-way pager, handheld electronic device, and combinations thereof; and
said mobile electronic device is of a compact size for readily fitting in a shirt pocket, pants pocket, suit pocket, and/or purse.

19. A mobile electronic device in accordance with claim 18 wherein:
said keypad comprises moldprint keypad with graphics on an underside of said keypad or on a layer below said keypad; and
said graphics selected from the group consisting of text, numbers, characters, alpha numeric images, color graphics, black graphics, moving graphics, animation, video clips, logos, photographs, decorations, designs, symbols, images, and combinations thereof.

20. A mobile electronic device in accordance with claim 17 wherein:
said keypad includes an imager selected from the group consisting of camera, camera lens, zoom lens, webcam, and image-capture device;
said keypad includes a flash positioned in proximity to said imager, said flash is selected from the group consisting of a light-emitting diode, light-emitting bulb, and an illumination source;
said keypad assembly includes a light barrier for substantially preventing the flash from illuminating graphics on said keypad and for substantially minimizing hot spots in images captured by said imager; and
said light barrier comprises a light-blocking gasket for substantially preventing the backlighting from being visible through the imager and about the flash.
